(19) United States
(12) Patent Application Publication
(10) Pub. No.: US 2026/0371537 A1
(43) Pub. Date: Nov. 19, 2026

(54) HEAT TRANSFER UNIT

(71) Applicant: DEIF A/S, Skive (DK)

(72) Inventors: Claus Bækgaard, Skive (DK); Lars Bo Pedersen, Skive (DK); Stig Lund Pallesgaard, Skive (DK)

(73) Assignee: DEIF A/S, Skive (DK)

(21) Appl. No.: 19/155,190

(22) PCT Filed: Feb. 8, 2024
(86) PCT No.: PCT/EP2024/053173

§ 371 Date: Aug. 8, 2025

(30) Foreign Application Priority Data
Feb. 10, 2023 (DK) PA20370076

(51) Int. Cl. H05K 7/20

(52) U.S. Cl. CPC H05K 7/20927; H05K 7/20254; H05K 7/20272

(57) ABSTRACT

A heat transfer unit is arranged to transfer heat to or from a thermal element mountable on the unit. The unit has a first outlet distribution channel connected to the outlet channel, a first inlet distribution channel connected to the inlet channel, a second outlet distribution channel connected to the outlet channel, and a barrier element. The unit further has a first inlet opening associated with the first inlet distribution channel, a first outlet opening associated with the first outlet distribution channel, and a second outlet opening associated with the second outlet distribution channel. The total area of the first inlet opening is less than the total area of the first outlet opening and less than the total area of the second outlet opening. An effective heat transfer unit with low pressure drop can thus be implemented.

The current invention relates to a heat transfer unit suitable to transfer heat to or from a thermal element which is mountable on the heat transfer unit.

According to the current invention, the term “heat transfer unit” is understood as a unit which can transfer heat to or from a thermal element. When heat is transferred from the thermal element to the heat transfer unit, the heat transfer unit could be called a cooling unit. When heat is transferred from the heat transfer unit to the thermal element, the heat transfer unit could be called a heating unit.

A “thermal element” is understood as an element which either generates heat or absorbs heat at a certain time. Its role could change depending on its state. An example of a thermal element which generates heat and transfers it to the heat transfer unit is an electric power module. An example of a thermal element which absorbs heat from the heat transfer unit is an air cooled heat sink. The air cooled heat sink absorbs heat from the heat transfer unit and releases it to the air surrounding the air cooled heat sink.

In most cases, the heat transfer unit according to the current invention is used as a cooling unit, where a thermal element which generates heat, for example an electric power module, is mounted on the heat transfer unit and heat is transferred from the thermal element to the heat transfer unit. However, the heat transfer unit of the current invention could also be used to transfer heat from a fluid passing through the heat transfer unit to a cooling device, for example an air cooled heat sink. One could imagine an example where a first heat transfer unit according to the current invention is provided with an electric power module at a first location. The first heat transfer unit is in fluid communication with a second heat transfer unit according to the current invention provided with an air fin based heat sink at a second location. Heat from the electronic power module is absorbed from the electric power module at the first location and then released to the air at the second location.

### DESCRIPTION OF RELATED ART

It is well known in the art of power electronics, that electric power modules generate heat. In order to maintain the performance and safety of the electric power modules, the power modules need to be actively cooled. Many different options of cooling are available in the art. In early power modules, air cooling was used, but due to increased power being handled in current power modules, the cooling demands have increased. As it is typically desired to have compact cooling modules, liquid cooling units are typically used today since liquid is a better heat conductor than air. As such many advanced liquid cooling units are available today. Such units can also be optimized for longevity as well as being more flexible than air cooled units, since heated water can be led away from the power module location to an external location via a hose or pipe where the heat can be dissipated more effectively or more safely.

One example of a liquid cooling unit for an electric power module is disclosed in EP1331665. This cooling unit proposes a two-level design, one for inlet and one for outlet. The resulting unit is quite complicated due to the long thin tubes necessary to transport the cooling liquid between the inlet level and the outlet level to the electric power module. The complicated arrangement also increases the pressure drop over the unit significantly.

Another example of a cooling unit is provided in EP2207201. Here inlet and outlet openings are provided into cells with meandering walls with turns guiding the liquid. Each 90° direction change of the water creates a pressure drop. Hence, a large pressure drop is experienced over this type of cooling unit.

### SUMMARY OF THE INVENTION

It is a first aspect of the current invention to provide a heat transfer unit with a more uniform temperature exchange over the entire surface of the unit. This increases the effectiveness of the unit and ensures that a thermal element mounted on the unit is cooled more uniformly.

A second aspect of the current invention is to provide a heat transfer unit with a low pressure drop across the unit. This will reduce the pump power required to force coolant fluid through the unit.

A third aspect of the current invention is to provide a heat transfer unit with a low thermal resistance between the unit and a thermal element mounted on the unit.

These aspects are provided via a heat transfer unit according to claim 1.

Due to this arrangement, a heat transfer unit with a low pressure drop over the unit is provided while still maintaining efficient cooling of the thermal element, even at low coolant fluid flow rates. Furthermore, by maintaining a narrow distance between a bottom surface of a thermal element mounted on the unit and the upper surface of the barrier element of the unit, the coolant fluid speed is increased over the entire surface. This leads to a more effective cooling.

It should be noted that in the current specification, the term coolant fluid is used. This term is to be interpreted quite broadly. In most cases, the coolant fluid will be a liquid. Some non-limiting examples of a coolant fluid are water, brine and oil. Different additives could be added to improve the properties, for example adding glycol to water to prevent freezing, adding lubricants to provide lubrication, adding additives to increase the boiling temperature, etc. However, in certain more advanced units, the fluid could be in different states in different portions of the device. For example, in one portion of the device, the fluid could be a liquid and in another part, the fluid could be a gas. In this way, the energy required for evaporation and the energy released during condensation, can be harnessed to increase the heat transfer effect.

It should also be noted, that in the current specification the phrase “the total area of the at least one opening associated with the distribution channel”, should be understood such that the total area of all the openings associated with the specific distribution channel are included. For example, in the embodiments shown in the figures, there are three inlet openings associated with each inlet distribution channel. Hence, the “total area of the at least one first opening associated with the first inlet distribution channel” should be understood to be the total area of the three inlet openings associated with the first inlet distribution channel.

It should also be noted that in the orientation shown in the figures, the outwards facing surface of the barrier element, is also an upper surface of the barrier element. In general, the outwards facing surface should be understood as a surface facing an interface surface of the thermal element when the thermal element is mounted on the unit.

In some embodiments, the total area of the at least one first inlet opening associated with the first inlet distribution channel is less than the total area of the at least one second outlet opening associated with the second outlet distribution channel.

In some embodiments, the offset distance between the outwards facing surface of the barrier element and the thermal unit is greater than 0.2 mm, 0.4 mm or 0.6 mm. In some embodiments, the offset distance is less than 2.5 mm, 2 mm or 1.5 mm. In some embodiments, the offset distance is 1 mm.

In some embodiments, the heat transfer unit further comprises a second inlet distribution channel arranged adjacent to and parallel to the second outlet distribution channel and at least one second inlet opening associated with the second inlet distribution channel, said at least one second inlet opening passing through the barrier element such that the outwards facing surface of the barrier element is in fluid communication with said second inlet distribution channel and in that the total area of the at least one second inlet opening associated with the second inlet distribution channel is less than the total area of the at least one second outlet opening associated with the second outlet distribution channel. In some embodiments, the total area of the at least one second inlet opening associated with the second inlet distribution channel is less than the total area of the at least one first outlet opening associated with the first outlet distribution channel.

In some embodiments, the first inlet and first outlet distribution channels are arranged as a first pair and the second inlet and second outlet distribution channels are arranged as a second pair. In some embodiments, third, fourth, fifth or more pairs of inlet and outlet distribution channels with associated inlet and outlet openings are arranged adjacent to each other in a similar fashion to the first and second pairs and having similar size relationships.

In some embodiments where there are multiple inlet distribution channels and multiple outlet distribution channels, flow limiting elements could be arranged between certain inlet and outlet openings to control the flow of fluid between certain inlet openings and certain outlet openings. For example, in an embodiment having an arrangement with a first inlet distribution channel, a first outlet distribution channel, a second inlet distribution channel and a second outlet distribution channel, in this order, a flow-limiting element in the shape of a wall could be arranged between the first outlet distribution channel and the second inlet distribution channel. In this way, fluid being injected via the at least one first inlet opening associated with the first inlet distribution channel will only go to the at least one first outlet opening associated with the first outlet distribution channel, since it will be prevented from going to the at least one second outlet opening due to the wall which is arranged to block the fluid flow. Other options for controlling the flow inside the unit are also possible depending on the desired functionality.

In some embodiments, the barrier element is a plate element and the flat outwards facing surface of the barrier element is an outwards facing surface of said plate element. In some embodiments, the plate element has a thickness of greater than 1 mm and less than 1 mm. In some embodiments, the heat transfer unit comprises spacer elements arranged between the outwards facing surface of the barrier element and a thermal element when the thermal element is mounted on the heat transfer unit. In some embodiments, the barrier element and the inlet and outlet distribution channels are portions of the same physical part.

In some embodiments, the heat transfer unit comprises a manifold element and where the first inlet distribution channel and the first and second outlet distribution channels are part of the manifold element. In some embodiments, the manifold element is an injection-moulded element.

In some embodiments, the barrier element is a separate element from the manifold element. In some embodiments, the manifold element is joined to the barrier element, for example via an adhesive or a weld. In some embodiments, the join between the barrier element and the manifold element is a sealed join.

In some embodiments, the at least one first inlet opening associated with the first inlet distribution channel is arranged as an oblong hole. In some embodiments, the at least one first inlet opening is a round hole.

In some embodiments, the at least one first inlet opening associated with the first inlet distribution channel comprises at least two first inlet openings. In some embodiments, the at least one first inlet opening comprises at least three inlet openings. In some embodiments having multiple inlet distribution channels, multiple inlet distribution channels are associated with multiple inlet openings.

In some embodiments having at least two first inlet openings, the at least two first inlet openings are arranged along a linear path. In some embodiments, the linear path is arranged along the longitudinal axis of the first inlet distribution channel with which the at least two first inlet openings are associated.

In some embodiments, the at least one first outlet opening associated with the first outlet distribution channel is arranged as an oblong hole and/or in that the at least one second outlet opening associated with the second outlet distribution channel is arranged as an oblong hole. In some embodiments, the total length of the at least one first outlet opening and/or the total length of the at least second outlet opening is greater than the total length of the at least one first inlet opening. In some embodiments, the length of the at least one first and/or the at least one second outlet opening is at least 50%, at least 65% or at least 80% of the length of the outlet distribution channel it is associated with.

In some embodiments, the at least one outlet opening associated with an outlet distribution channel is arranged parallel to the at least one inlet opening associated with an inlet distribution channel adjacent to the outlet distribution channel. In some embodiments, the at least one outlet opening of both the first and second outlet distribution channels are parallel to the inlet opening of the first inlet distribution channel.

In some embodiments, the first outlet distribution channel and the second outlet distribution channel have the same cross sectional area and/or the same length. For the sake of this specification and this statement, the cross sectional area is defined in a plane which is perpendicular to a longitudinal axis of the outlet distribution channel. In some embodiments where there are multiple inlet distribution channels, at least two of said multiple inlet distribution channels have the same cross sectional area and/or the same length. In some embodiments where there are a plurality of inlet distribution channels, all of said plurality of distribution channels have the same cross sectional area and the same length. In some embodiments where there are a plurality of outlet distribution channels, all of said plurality of distribution channels have the same cross sectional area. In some embodiments, the plurality of inlet and/or outlet distribution channels comprises three, four, five, or six distribution channels.

It should be emphasized that the term “comprises/comprising/comprised of” when used in this specification is taken to specify the presence of stated features, integers, steps or components but does not preclude the presence or addition of one or more other features, integers, steps, components or groups thereof. For example, if a claim states that the unit comprises four inlet distribution channels, this should be understood as “at least four inlet distribution channels”. In other words, units with five or six or more distribution channels would also be covered.

### BRIEF DESCRIPTION OF THE DRAWINGS

In the following, the invention will be described in greater detail with reference to embodiments shown by the enclosed figures. It should be emphasized that the embodiments shown are used for example purposes only and should not be used to limit the scope of the invention.

FIG. 1 shows a front top perspective view of a heat transfer unit according to the invention with an electric power module mounted on it.

FIG. 2 shows a front top perspective view of the heat transfer unit of FIG. 1 without the power module.

FIG. 3 shows a front top exploded perspective view of the heat transfer unit of FIG. 1.

FIG. 4 shows a section view of the heat transfer unit of FIG. 1 according to the line IV-IV defined in FIG. 1.

FIG. 5 shows a top view of a barrier element of the heat transfer unit of FIG. 1.

FIG. 6 shows a top view of an alternative embodiment of a barrier element.

### DETAILED DESCRIPTION OF THE EMBODIMENTS

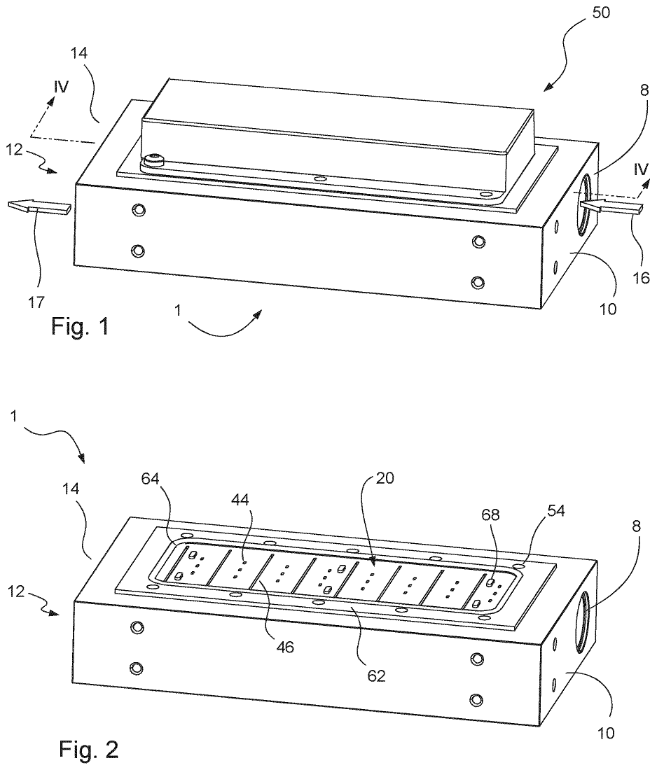

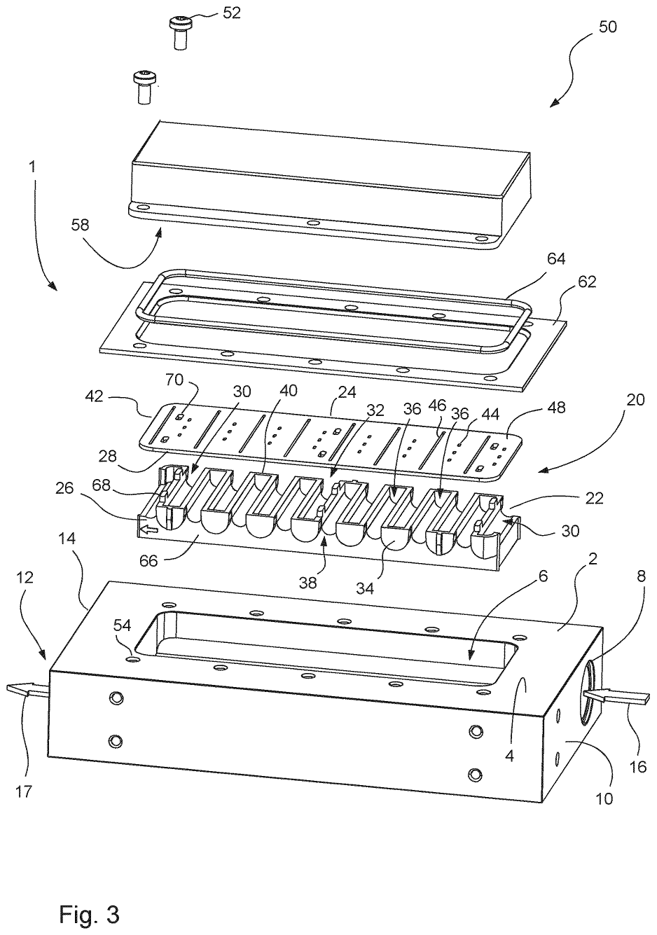

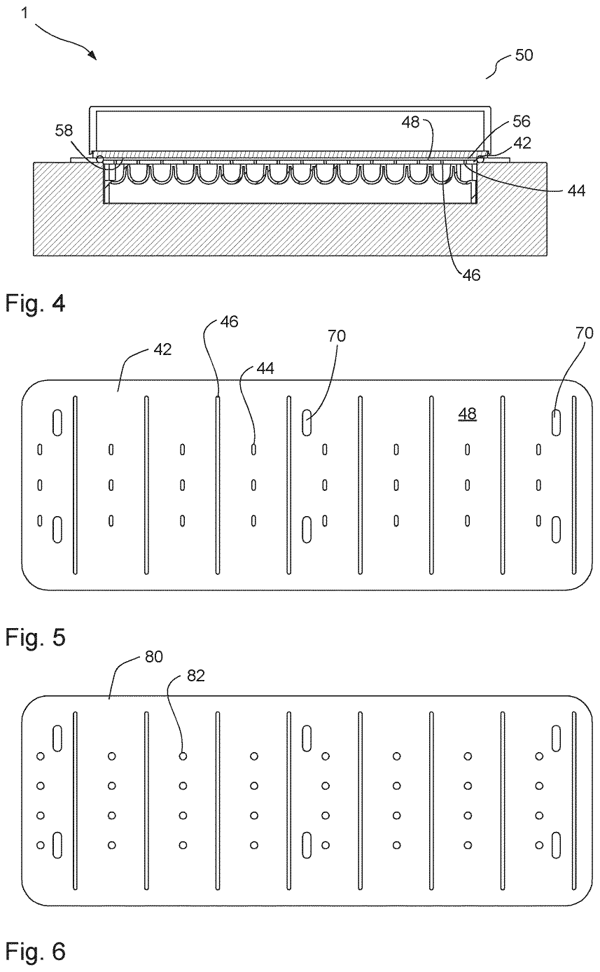

FIGS. 1-5 show different views and/or different components of a first embodiment 1 of a heat transfer unit according to the current invention and a thermal element 50, in the form of an electric power module 50 mounted on the heat transfer unit. The electric power module is fastened to the heat transfer unit via screws 52. The electric power module in the figures is shown schematically. Electric power modules are known in the art and won't be described further in this specification. As mentioned earlier on, the heat transfer unit according to the invention can be used with many different kinds of thermal elements. Common for these thermal elements is a flat interface surface 58 (on the bottom of the module in the embodiment shown in the figures) of the thermal element. The thermal elements are designed such that the main heat transfer occurs via this flat interface surface.

The embodiment of the heat transfer unit 1 shown in FIGS. 1-4 comprises a rectangular aluminium block 2 with a flat upper surface 4. A rectangular recess 6 is formed in the upper surface of the aluminium block. A first circular bore 8 is provided in one end surface 10 of the aluminium block. Said first circular bore provides a fluid connection between the end surface 10 and the rectangular recess formed in the block. A second circular bore 12 is provided on an opposite end surface 14 of the block. The second circular bore is hidden in the orientation shown in the figures, but it can be imagined to be on an opposite side in a similar manner, but arranged closer to the forward surface of the block, as illustrated by the output arrow 17. The second circular bore provides a fluid connection between the opposite end surface and the rectangular recess formed in the block.

Via suitable fittings (not shown) coolant fluid, for example water with or without suitable additives known in the art, can be injected into the rectangular recess via the first circular bore 8 and ejected from the rectangular recess via the second circular bore 12. In the figures, the flow is shown from the first to the second circular bore via the input arrow 16 and the output arrow 17, however the opposite flow direction could also be imagined. Likewise, in another embodiment (not shown), the inlet and outlet fittings could be located on the same side of the block. Or they could be located on the bottom and/or the top of the block, depending on the arrangement of the channels inside the block. Many options are possible, as will be known to the person skilled in the art.

While the current embodiment uses an aluminium block, other embodiments could use other materials or other shapes. In certain embodiments (not shown), a plastic or polymeric block could be considered. As should be clear to the person skilled in the art, many options for suitable materials are available.

A distribution element 20 is provided inside the rectangular recess. The distribution element is formed complementary to the rectangular recess in the aluminium block so that it essentially fills the rectangular recess. The distribution element has an elongated recess 22 arranged along a first long side 24 of the distribution element. The recess 22 forms an inlet channel 22 together with the side and bottom of the rectangular recess in the aluminium block when the distribution element is arranged inside the rectangular recess. A second elongated recess 26 is arranged along the opposite long side 28 of the distribution element and forms an outlet channel 26 together with the side and bottom of the rectangular recess in the aluminium block when the distribution element is arranged inside the rectangular recess.

The inlet channel is arranged such that coolant fluid entering the rectangular recess via the first circular bore 8 enters the inlet channel and flows along the inlet channel along the entire length of the first long side 24 of the distribution element. The dimensions of the inlet channel are chosen to ensure that the pressure of the coolant fluid in the inlet channel is essentially constant along the length of the channel. The outlet channel is arranged in fluid connection with the second circular bore 12. Coolant fluid in the outlet channel is able to flow along the opposite long side 28 of the rectangular recess and leave the rectangular recess via the second circular bore. Again, the dimensions of the outlet channel are chosen to ensure that the pressure in the outlet channel is essentially constant along the length of the outlet channel.

The inlet channel is connected to a plurality of inlet distribution channels 30. The inlet distribution channels are parallel to each other and arranged offset from each other along the length of the distribution element. In this embodiment, the inlet distribution channels are arranged perpendicular to the length of the inlet channel, however, in other embodiments, other arrangements could be imagined. Each of the inlet distribution channels is in fluid connection with the inlet channel at one end 32 of the inlet distribution channel and blocked at the other end 34. Likewise, the outlet channel is connected to a plurality of outlet distribution channels 36. Like the inlet distribution channels, the outlet distribution channels are also arranged parallel to each other and offset from each other along the longitudinal axis of the distribution element. Again, as with the inlet distribution channels, the outlet distribution channels in this embodiment are arranged perpendicular to the length of the outlet channel. The outlet distribution channels are each in fluid connection with the outlet channel at a first end 38 of the outlet distribution channel and blocked at the other end 40. Since the inlet and outlet channels are arranged on either side of the distribution element, the input and output distribution channels are mirrored and the open ends and closed ends are opposite with the inlet and outlet distribution channels. Other arrangements could also be imagined.

As can be seen in the figures, the inlet and outlet distribution channels alternate along the longitudinal axis of the distribution element. Hence, each inlet distribution channel has at least one adjacent outlet distribution channel. It could be said that the inlet and outlet distribution channels in the current embodiments are arranged as pairs and that there are 8 pairs of distribution channels.

Due to the size and shape of the inlet distribution channels, when fluid is present in the inlet channel, it will flow into the inlet distribution channels and the pressure in all the inlet distribution channels as well as the inlet channel will be essentially identical. Likewise, due to the size and shape of the outlet distribution channels, when fluid is present in the outlet distribution channels, it will flow into the outlet channel and the pressure in all the outlet distribution channels as well as the outlet channel will be essentially constant.

A barrier element 42 in the form of a plate is arranged on top of the inlet and outlet distribution channels. The inlet and outlet distribution channels are arranged as U shaped channels which are open at their top. The barrier element is arranged such that one major surface of the plate is pressed against the upper surface of the U shaped channels to essentially close them.

The barrier element further has a series of inlet openings 44 and a series of outlet openings 46 arranged as through going openings, passing through the thickness of the plate. The inlet openings 44 are arranged such that the upper surface 48 of the plate is in fluid communication with the inlet distribution channels and the outlet openings are arranged such that the upper surface 48 of the plate is in fluid communication with the outlet distribution channels.

In this way, fluid entering the inlet channel via the first circular bore will be distributed to the inlet distribution channels and then ejected through the inlet openings at a high pressure. Fluid will then impinge on the flat interface surface 58 of the power module 50 at high speed and be redirected back towards the upper surface 48 of the barrier element. The fluid trapped between the upper surface of the distribution plate and the power module will have a pressure which is higher than the pressure in the outlet distribution channels. Hence, the fluid will be forced through the outlet openings and into the outlet distribution channels and then further to the outlet channel to exit the rectangular recess via the second circular bore.

As mentioned above, the heat transfer unit is arranged such that a power module 50 can be mounted on the unit via screws 52. The screws engage threaded holes 54 arranged around the periphery of the rectangular recess in the aluminium block. The unit is arranged such that a flat interface surface of the power module is arranged at a slight offset from the upper surface 48 of the barrier element. In this way, a slight gap 56 is formed between the flat interface surface 58 of the power module and the upper surface 48 of the barrier element. Liquid will be forced into this gap via the inlet openings in the barrier element and leave the gap via the outlet openings in the barrier element. Due to the relatively small gap between the barrier element and the interface surface of the power module, the speed of the fluid flow will be quite high, thereby leading to high levels of heat transfer.

In the current embodiment, in order to seal the connection between the power module and the heat transfer unit, a flat plastic plate element 62 and an o-ring 64 are arranged between the power module and the aluminium block. The o-ring 64 is arranged in a rectangular groove in the flat plastic plate element around the periphery of the rectangular recess to provide an effective seal between the aluminium block and the power module. When the power module is pressed onto the aluminium block, the o-ring is compressed. Other sealing arrangements are also possible. For example, in one embodiment (not shown), a rectangular groove could be formed directly in the aluminium block and an o-ring could be arranged directly in the rectangular groove. The o-ring would be compressed between the power module and the aluminium block when the power module is pressed onto the aluminium block.

In the embodiment shown in the figures, eight inlet distribution channels and eight outlet distribution channels are provided. The barrier element has three inlet openings connected to each inlet distribution channel. The inlet openings are all arranged as oblong holes with a dimension of 3 mm long and 1 mm wide. The three inlet openings are arranged inline with each other along a linear path which is arranged along the longitudinal extension of the inlet distribution channel with which the inlet openings are associated. The barrier element of the current embodiment has a single outlet opening associated with each outlet distribution channel. The outlet openings are each an oblong hole which is 50 mm long and 1 mm wide. The total area of the three inlet openings associated with a particular inlet distribution channel is smaller than the area of a single outlet opening associated with an adjacent outlet distribution channel. Hence, fluid will be injected at a high pressure via the inlet openings and then be able to easily leave through the larger outlet opening.

It should be noted that the dimensions of the different components and the pump capacity are chosen to ensure essentially identical flow through all the inlet openings. This is of course based on the expected rate of flow of coolant fluid through the unit. At higher flow rates, the dimensions will need to be increased as will be known to the person skilled in the art of fluid dynamics.

In the embodiment shown, the distribution element 20 is formed as a two piece unit where a lower piece 66 comprises the distribution channels and a barrier element is mounted on the lower piece. The lower piece could also be considered a type of manifold element which redirects coolant fluid within the unit. Rectangular tabs 68 on the lower piece are engaged with rectangular openings 70 on the barrier element and pass through these openings. This ensures the position of the barrier element with respect to the lower piece and hence the distribution channels. The tabs are furthermore arranged such that they extend up above the upper surface of the barrier element and press up against the interface surface of the power module. In this way, they ensure that the gap between the power module and the barrier element is constant. In the current embodiment, the lower piece and the barrier element are joined together via an adhesive to form a single unit which is placed in the rectangular recess in the aluminium block. It is considered that in one embodiment (not shown), the lower piece could be manufactured as an injection moulded component with the inlet and outlet channels as well as the inlet and outlet distribution channels. The barrier element could be manufactured from a single plate element which is cut to the correct shape and provided with suitable inlet/outlet openings.

FIG. 6 shows another embodiment of a barrier element 80. The general principle of operation is the same as the first barrier element shown in FIG. 5, however, instead of providing oblong rectangular holes as the inlet openings, in this case round holes 82 are provided. It has been found that the performance of the oblong holes is better than the round holes, however, the overall effect is similar. Furthermore, the oblong holes could have a greater tolerance to particles in the cooling liquid and a distribution element with oblong inlet openings might prove to be blocked less frequently than a plate with round openings. However, other arrangements of openings could be provided within the scope of the invention.

This distribution element design can furthermore be adjusted to a specific module type by resizing the barrier element, adding additional inlets and/or outlets and/or resizing and/or changing the placement of the inlets and/or outlets. If a longer and narrower power module were to be cooled, then a design could be chosen for the distribution element which was longer and narrower. Likewise, the number and size of the distribution channels can also be adjusted to the specific thermal element which is to be mounted on the heat transfer unit. If the specific locations of the highest temperature zones on the thermal element are known, then the inlet openings could be arranged to inject fluid directly at the highest temperature areas. Many different arrangements are possible within the scope of the current invention.

In some embodiments, instead of providing a distribution element arranged inside a block with a recess, it could be imagined that the block+distribution element could be provided in different combinations. For example, in one embodiment, the block+lower part could be formed as a single piece, for example via 3D printing and then a barrier plate could be mounted on the combined block and lower part. In another embodiment, the block and lower part could be formed via a casting operation which is then further machined. Many options are available to the person skilled in the art.

In the embodiments shown in the figures, the barrier element was mounted on the manifold element to form a distribution element. However, within the scope of the current invention, certain parts could be integrated with the thermal element instead. For example, in one embodiment (not shown), the barrier element could be fastened to the thermal element itself. Then when the thermal element is mounted on the block, the barrier element is pressed against the manifold part. Or in another embodiment (not shown), a distribution element could be fastened directly to the thermal element. For example, the manifold part and the barrier element could be attached to the thermal element. Then when the thermal element is mounted on the block, the distribution element is inserted into the rectangular recess. Many different combinations could be imagined.

In the figures, an electric power module is mounted on the heat transfer unit. In this case, the power module generates heat and the heat transfer unit can be described as a cooling unit which cools the power module. However, in another embodiment (not shown), instead of mounting a power module on the heat transfer unit of the current invention, a heat dissipater could be mounted on the heat transfer unit. For example a finned heat sink with a flat bottom interface surface could be mounted on the heat transfer unit. In this case, hot liquid could be injected into the heat transfer unit and then the hot liquid would be injected against the bottom surface of the finned heat sink. Heat would then be transferred from the liquid to the air outside the assembly via the fins. In this case the energy flow is reversed when compared to the embodiments shown in the figures. As such, instead of being called a cooling module, the unit is called a heat transfer unit to cover the invention more broadly.

is to be noted that the figures and the above description have shown the example embodiments in a simple and schematic manner. Many of the specific mechanical details have not been shown since the person skilled in the art should be familiar with these details and they would just unnecessarily complicate this description. For example, the specific materials used and the specific injection moulding procedure have not been described in detail since is maintained that the person skilled in the art would be able to find suitable materials and suitable processes to manufacture the heat transfer unit according to the current invention.

1. A heat transfer unit arranged to transfer heat to or from a thermal element which is mountable on the heat transfer unit, said thermal element being of the kind having a flat interface surface which is to be heated or cooled respectively, said heat transfer unit comprising:
a. an inlet channel for supplying coolant fluid to the heat transfer unit,
b. an outlet channel for transferring coolant fluid away from the heat transfer unit,
c. a first outlet distribution channel connected to the outlet channel,
d. a second outlet distribution channel connected to the outlet channel and arranged parallel to the first outlet distribution channel,
e. a first inlet distribution channel connected to the inlet channel and arranged parallel to and between the first and second outlet distribution channels such that the first inlet distribution channel is adjacent to both the first and the second outlet distribution channels,
f. a barrier element arranged between the thermal element and the first inlet and the first and second outlet distribution channels when the thermal element is mounted on the heat transfer unit, said barrier element having a flat outwards facing surface that it is arranged parallel to and offset a distance from the flat interface surface of the thermal element when the thermal element is mounted on the heat transfer unit, said distance being greater than 0.1 mm and less than 3 mm,
g. at least one first inlet opening associated with the first inlet distribution channel, said at least one first inlet opening passing through the barrier element such that said flat outwards facing surface is in fluid communication with the first inlet distribution channel via said at least one first inlet opening,
h. at least one first outlet opening associated with the first outlet distribution channel, said at least one first outlet opening passing through the barrier element such that said flat outwards facing surface is in fluid communication with said first outlet distribution channel, and
i. at least one second outlet opening associated with the second outlet distribution channel, said at least one second outlet opening passing through the barrier element such that said flat outwards facing surface is in fluid communication with said second outlet distribution channel;
wherein:
the total area of the at least one first inlet opening associated with the first inlet distribution channel is less than the total area of the at least one first outlet opening associated with the first outlet distribution channel.

2. The heat transfer unit according to claim 1, wherein:
the barrier element is a plate element; and
the flat outwards facing surface is an outwards facing surface of said plate element.

3. The heat transfer unit according to claim 1, wherein:
the heat transfer unit comprises a manifold element; and
the first inlet distribution channel and the first and second outlet distribution channels are part of the manifold element.

4. The heat transfer unit according to claim 3, wherein:
the barrier element is a separate element from the manifold element.

5. The heat transfer unit according to claim 1, wherein:
the at least one first inlet opening associated with the first inlet distribution channel is arranged as an oblong hole.

6. The heat transfer unit according to claim 1, wherein:
the at least one first inlet opening associated with the first inlet distribution channel comprises at least two first inlet openings.

7. The heat transfer unit according to claim 6, wherein:
said at least two first inlet openings are arranged along a linear path.

8. The heat transfer unit according to claim 1, wherein:
the at least one first outlet opening associated with the first outlet distribution channel is arranged as an oblong hole; and/or
the at least one second outlet opening associated with the second outlet distribution channel is arranged as an oblong hole.

9. The heat transfer unit according to claim 1, wherein:
the at least one first outlet opening associated with the first outlet distribution channel is arranged parallel to the at least one first inlet opening associated with the first inlet distribution channel.

10. The heat transfer unit according to claim 1, wherein:
the first outlet distribution channel and the second outlet distribution channel have the same cross sectional area and/or the same length.

11. A heat transfer unit arranged to transfer heat to or from a thermal element which is mountable on the heat transfer unit, said thermal element being of the kind having a flat interface surface which is to be heated or cooled respectively, said heat transfer unit comprising:
a. an inlet channel for supplying coolant fluid to the heat transfer unit,
b. an outlet channel for transferring coolant fluid away from the heat transfer unit,
c. a first outlet distribution channel connected to the outlet channel,
d. a second outlet distribution channel connected to the outlet channel and arranged parallel to the first outlet distribution channel,
e. a first inlet distribution channel connected to the inlet channel and arranged parallel to and between the first and second outlet distribution channels such that the first inlet distribution channel is adjacent to both the first and the second outlet distribution channels,
f. a barrier element arranged between the thermal element and the first inlet and the first and second outlet distribution channels when the thermal element is mounted on the heat transfer unit, said barrier element having a flat outwards facing surface that it is arranged parallel to and offset a distance from the flat interface surface of the thermal element when the thermal element is mounted on the heat transfer unit, said distance being greater than 0.1 mm and less than 3 mm,
g. at least one first inlet opening associated with the first inlet distribution channel, said at least one first inlet opening passing through the barrier element such that said flat outwards facing surface is in fluid communication with the first inlet distribution channel via said at least one first inlet opening,
h. at least one first outlet opening associated with the first outlet distribution channel, said at least one first outlet opening passing through the barrier element such that said flat outwards facing surface is in fluid communication with said first outlet distribution channel, and
i. at least one second outlet opening associated with the second outlet distribution channel, said at least one second outlet opening passing through the barrier element such that said flat outwards facing surface is in fluid communication with said second outlet distribution channel;
wherein:
the total area of the at least one first inlet opening associated with the first inlet distribution channel is less than the total area of the at least one first outlet opening associated with the first outlet distribution channel;
the barrier element is a plate element;
the flat outwards facing surface is an outwards facing surface of said plate element;
the heat transfer unit comprises a manifold element;
the first inlet distribution channel and the first and second outlet distribution channels are part of the manifold element;
the barrier element is a separate element from the manifold element;
the at least one first inlet opening associated with the first inlet distribution channel is arranged as an oblong hole;
the at least one first inlet opening associated with the first inlet distribution channel comprises at least two first inlet openings;
said at least two first inlet openings are arranged along a linear path;
the at least one first outlet opening associated with the first outlet distribution channel or the at least one second outlet opening associated with the second outlet distribution channel is arranged as an oblong hole;
the at least one first outlet opening associated with the first outlet distribution channel is arranged parallel to the at least one first inlet opening associated with the first inlet distribution channel; and
the first outlet distribution channel and the second outlet distribution channel have the same cross sectional area and/or the same length.
